(19) United States
(12) Patent Application Publication
(10) Pub. No.: US 2025/0091260 A1
(43) Pub. Date: Mar. 20, 2025

(54) METHOD FOR MANUFACTURING RESIN SHEET BY USING 3D PRINTER, AND POLISHING PAD HAVING POLISHING LAYER OBTAINED THEREBY

(71) Applicant: KURARAY CO., LTD., Kurashiki-shi, Okayama (JP)

(72) Inventors: Mitsuru KATO, Kurashiki-shi, Okayama (JP); Takashi SUGIOKA, Kurashiki-shi, Okayama (JP)

(73) Assignee: KURARAY CO., LTD., Kurashiki-shi, Okayama (JP)

(21) Appl. No.: 18/832,573

(22) PCT Filed: Jan. 30, 2023
(86) PCT No.: PCT/JP2023/002861

§ 371 Date: Jul. 24, 2024

(30) Foreign Application Priority Data
Jan. 31, 2022 (JP) 2022-013320

(51) Int. Cl. B29C 43/02; B24D 11/00; B29C 43/52; B29C 43/56; B29K 75/00; B29L 31/00; B33Y 40/20

(52) U.S. Cl. CPC B29C 43/021; B24D 11/008; B29C 43/52; B29C 43/56; B29C 2043/561; B29K 2075/00; B29L 2031/736; B33Y 40/20

(57) ABSTRACT

The present invention relates to a method for producing a resin sheet containing at least the following step P, Step P: a step of applying pressure (p) to a sheet-shaped resin modeled article formed by a 3D printer while heating, and deforming the sheet-shaped resin modeled article to obtain a compressed sheet; and relates to a polishing pad containing a polishing layer obtained by using the method for producing.

### TECHNICAL FIELD

The present invention relates to a method for producing a resin sheet by a 3D printer, and a polishing pad containing a polishing layer obtained thereby.

### BACKGROUND ART

In recent years, so-called 3D printing technology has been used as a technology for three-dimensionally forming a resin materials based on blueprints of three dimensional data such as 3D CAD and 3D CG.

3D printers are becoming popular among the public as devices which employ 3D printing technology. For example, when forming a modeled article of resin using a 3D printer, it is possible to form a resin modeled article without using a modeling machine (for example, a die or a mold for molding a specific shape) which is adapted to a specific modeled article, as in the past.

As examples of a forming method for forming a resin materials using 3D printing technology, various methods such as a fused deposition modeling method (FDM (Fused Deposition Modeling)) in which a modeled article is formed by heating and melting a thermoplastic resin and being extruded from a nozzle, and laminating one layer by one layer on a modeling table; a stereo lithography method (SLA (Stereo Lithography Apparatus)) in which a three-dimensional modeled article is formed while curing a curable resin one layer by one layer, by irradiating energy rays such as ultraviolet rays to a photocurable liquid resin; and an inkjet method in which a resin cured product is laminated while curing with energy rays after injection from an ink head, by replacing an ink in an inkjet printer with an energy-curable resin, are known.

In addition, an example of the modeled article formed by using 3D printing technology includes a polishing layer which is used for a polishing pad used in a polishing method for planarizing a surface of semiconductor wafer. A typical example of the polishing pad includes a polishing pad used in a polishing method for planarizing a surface of semiconductor wafer by a polishing method of CMP (Chemical Mechanical Polishing (Planarization)).

For example, in Patent Literature 1, as a method for forming a groove on a polishing pad for CMP, 3D printing method is described.

Further, in Patent Literature 2, a method for producing a polishing layer of a polishing pad, in which laminating a plural layers in sequence using a 3D printer is contained, and each layer of the plural polishing layers is laminated by jetting a precursor of pad materials from a nozzle and solidifying the precursor of pad materials to form a solidified pad material, is described.

Furthermore, in Patent Literature 3, a method for producing a polishing layer of the polishing pad formed from polymer matrix in which particles are embedded in a desired distribution, using a 3D printer, is described.

In addition, in Patent Literature 4, a method for producing a porous polishing pad by vaporizing a porosity-forming agent through an anneal treatment to heat to low temperatures (for example, 100° C.) under low pressure, is described.

### CITATION LIST

### Patent Literature

PTL1: JP2008-507417A
PTL 2: JP2015-517922A
PTL 3: JP2016-536151A
PTL 4: JP2021-523025A

### SUMMARY OF INVENTION

### Technical Problem

By using 3D printing technology, it is possible to reduce a loss of resin materials, for example, compared to conventional methods such as extrusion molding method and injection molding method, resulting that advantages such as cost reduction and effective use of resources can be obtained.

On the other hand, the present inventors investigated and it was found that when resin is formed by using 3D printer, unlike the conventional method, the physical properties of the obtained resin sheet, especially the mechanical properties, tend to be inferior.

Therefore, in the polishing pads described in Patent Literatures 1 to 4, the polishing layer has low strength and low abrasion resistance, and is easily worn out by dressing treatment, therefore it is considered that the life (usable time) when used as a polishing pad will be shortened.

An object of the present invention is to provide a method for producing a resin sheet which can improve the mechanical properties of the resin sheet when forming a resin sheet by using a 3D printer.

### Solution to Problem

The present invention includes the following inventions.

[1]A method for producing a resin sheet containing at least the following step P, Step P: a step of applying pressure (p) to a sheet-shaped resin modeled article formed by a 3D printer while heating, and deforming the sheet-shaped resin modeled article to obtain a compressed sheet.

[2] The method for producing a resin sheet according to the above item [1],
in which the heat temperature in the step P is 80° C. or higher.

[3] The method for producing a resin sheet according to the above item [1] or [2],
in which the pressure (p) in the step P is 0.1 MPa or more.

[4] The method for producing a resin sheet according to any one of the above items [1] to [3],
in which a spacer is used in the step P.

[5] The method for producing a resin sheet according to any one of the above items [1] to [4],
in which the product of the pressure (p) and the time (t) for applying the pressure (p) satisfies the following formula (i), in the step P;

5≤p×t≤5000[a unit of p is MPa, a unit of t is second]. Formula (i):

[6] The method for producing a resin sheet according to any one of the above items [1] to [5],
in which the step P is performed under a reduced pressure atmosphere.

[7] The method for producing a resin sheet according to any one of the above items [1] to [6],
in which the resin modeled article is a modeled article of polyurethane in the step P.

[8] The method for producing a resin sheet according to any one of the above items [1] to [7], further containing the following step M before the step P,
Step M: a step of discharging a melt or a precursor of resin from a nozzle and solidifying it to form a sheet-shaped resin modeled article, using a 3D printer.

[9] The method for producing a resin sheet according to the above item [8],
in which the melt or the precursor of resin passes through a filter before discharged from the nozzle of the 3D printer, in the step M.

[10] The method for producing a resin sheet according to the above item [8] or [9],
in which the resin is a thermoplastic resin and the solidifying of the thermoplastic resin is performed by cooling, in the step M.

[11] The method for producing a resin sheet according to the above item [10],
in which the thermoplastic resin is a thermoplastic polyurethane, in the step M.

[12] The method for producing a resin sheet according to any one of the above items [1] to [11], further containing the following step T after the step P,
Step T: a step of making a thickness of the compressed sheet obtained in the step P thin using one or more methods selected from the group consisting of cutting, machining, and grinding.

[13] The method for producing a resin sheet according to any one of the above items [1] to [12],
in which the resin sheet is a polishing layer for a polishing pad.

[14]A polishing pad containing a polishing layer obtained by using the method for producing a resin sheet according to the above item [13].

### Advantageous Effects of Invention

According to the present invention, it is possible to provide a method for producing a resin sheet, which can improve the mechanical properties of the resin sheet when forming a resin sheet by using a 3D printer.

### BRIEF DESCRIPTION OF DRAWINGS

FIG. 1 is a schematic diagram illustrating an example of a method for forming a sheet-shaped resin modeled article by using a 3D printer.

FIG. 2 is a schematic cross-sectional diagram illustrating an example of a sheet-shaped resin modeled article which is formed by using a 3D printer before subjected to a step P according to the present invention.

FIG. 3 is a schematic cross-sectional diagram illustrating an example of a compressed sheet obtained by subjecting the sheet-shaped resin modeled article formed by using the 3D printer to the step P according to the present invention.

FIG. 4 is a schematic plan view illustrating an outline of a disc-shaped sheet and test pieces used in measurement of storage modulus in Examples.

### DESCRIPTION OF EMBODIMENTS

It will be explained in the following based on an example of the embodiments of the present invention. However, the embodiments shown below is an example for embodying the technical idea of the present invention, and the present invention is not limited to the following description.

The present invention also includes the embodiments in which the items described in this description are arbitrary selected or arbitrary combined.

In this description, preferred regulations may be arbitrary selected, and it can be said that the combination of the preferred regulations is more preferable.

In this description herein, unless otherwise indicated, the description of “XX to YY”, as the numerical range means “XX or more and YY or less”. For example, when simply described as “10 to 90” as a numerical range, it represents a range of 10 or more and 90 or less.

In this description, the lower limit values and the upper limit values described in stages for the numerical ranges (the content of each component, values calculated from the each component, each property, and the like) can be independently combined. For example, the expression of “preferably 10 to 90, more preferably 30 to 60” for the same item can mean “10 to 60” by combining “the preferable lower limit value (10)” and “the more preferable upper limit value (60)”.

Further, for the numerical range, for example based on the description of “preferably 10 to 90, more preferably 30 to 60”, the only lower limit value may be specified as “10 or more” or “30 or more” without particularly specifying the upper limit value, and similarly the only upper limit value may be specified as “90 or less” or “60 or less” without particularly specifying the lower limit value.

As described above, for example, the description of “preferably 10 or more, more preferably 30 or more” and the description of “preferably 90 or less, more preferably 60 or less” for the same item, can mean “10 or more and 60 or less” by combining “the preferable lower limit value (10)” and “the more preferable upper limit value (60)”. In addition, as described above, the only lower limit value may be specified as “10 or more” or “30 or more”, and similarly, the only upper limit value may be specified as “90 or less” or “60 or less”.

Furthermore, in this description, unless otherwise indicated, the expression of “mechanical properties” more specifically refers to “storage modulus”, “breaking stress”, “elongation at break” and “abrasion resistance” of the resin sheet and the polishing layer which are obtained by a method for producing a resin sheet which is one embodiment of the present invention.

[Method for Producing a Resin Sheet]A method for producing a resin sheet which is one embodiment of the present invention is characterized in that at least the following step P is contained.

Step P: a step of applying pressure (p) to a sheet-shaped resin modeled article formed by a 3D printer while heating, and deforming the sheet-shaped resin modeled article to obtain a compressed sheet.

Further, a method for producing a resin sheet which is one embodiment of the present invention preferably further contains the following step M before the step P.

Step M: a step of discharging a melt or a precursor of resin from a nozzle and solidifying it to form a sheet-shaped resin modeled article, using a 3D printer.

Further, a method for producing a resin sheet which is one embodiment of the present invention preferably further contains the following step T after the step P.

Step T: a step of making a thickness of the compressed sheet obtained in the step P thin using one or more methods selected from the group consisting of cutting, machining, and grinding.

In addition, a method for producing a resin sheet, which is one embodiment of the present invention, is not particularly limited as long as at least the above-described step P is contained as described above, and it may be an embodiment which contains the step M and the step P, may be an embodiment which contains the step P and the step T, and may be an embodiment which contains the step M, the step P, and the step T in this order. Further, each embodiment may further contain steps other than each step, and it may be an embodiment in which these steps may be carried out directly without passing through other steps.

Each step of the method for producing a resin sheet, which is one embodiment of the present invention, will be described below.

### <Step P>

The step P is a step of applying the pressure (p) to a sheet-shaped resin modeled article formed by a 3D printer while heating, and deforming the sheet-shaped resin modeled article to obtain a compressed sheet. Hereinafter, in this description, “sheet-shaped resin modeled article” is also simply referred to as “resin modeled article”.

For the following reasons, it is presumed that the mechanical properties of the resin sheet formed by a 3D printer are improved by being passed through the process P.

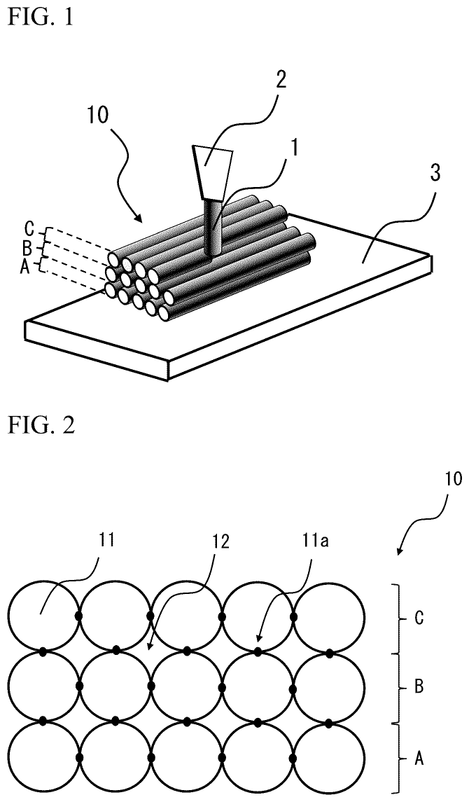

As described above, there are various methods for forming a sheet-shaped resin modeled article using a 3D printer. For example, a schematic diagram of an example of a resin forming method by a 3D printer is shown in FIG. 1. FIG. 1 shows that, as represented by the above-mentioned FDM method, a melt or its precursor 1 of the resin as a raw material, is extruded from a nozzle 2, and a resin modeled article 10 is formed by laminating one layer by one layer from the bottom onto a modeling table 3. When forming the one layer, the melt or its precursor 1 of the resin extruded from the nozzle 2 is arranged in order in the plane direction (two-dimensional) to form a first layer A, and then, a layer B, which is the second layer, is similarly formed by arranging the melt or its precursor 1 of the resin which is extruded from the nozzle 2, on the formed layer A, and the layer B will be laminated on the layer A. FIG. 1 illustrates that the state in which a layer C is further formed on the layer B. By repeating this operation several times, a plural layers are laminated, and finally a sheet-shaped resin modeled article is formed. Further, for example, as one embodiment of the sheet-shaped resin modeled article formed by using a 3D printer, it may be a sheet-shaped resin modeled article which is constituted by a single layer (for example, only the first layer A shown in FIG. 1), it is preferably a sheet-shaped resin modeled article formed by laminating a plural layers, as shown in FIG. 1.

FIG. 2 shows a schematic cross-sectional diagram according to an example of the sheet-shaped resin modeled article formed in this manner. The sheet-shaped resin modeled article 10 formed by a 3D printer, shown in FIG. 2, is constituted, for example, by the layer A as the first layer formed on the modeling table, the layer B as the second layer, and the layer C as the third layer in descending order from the bottom.

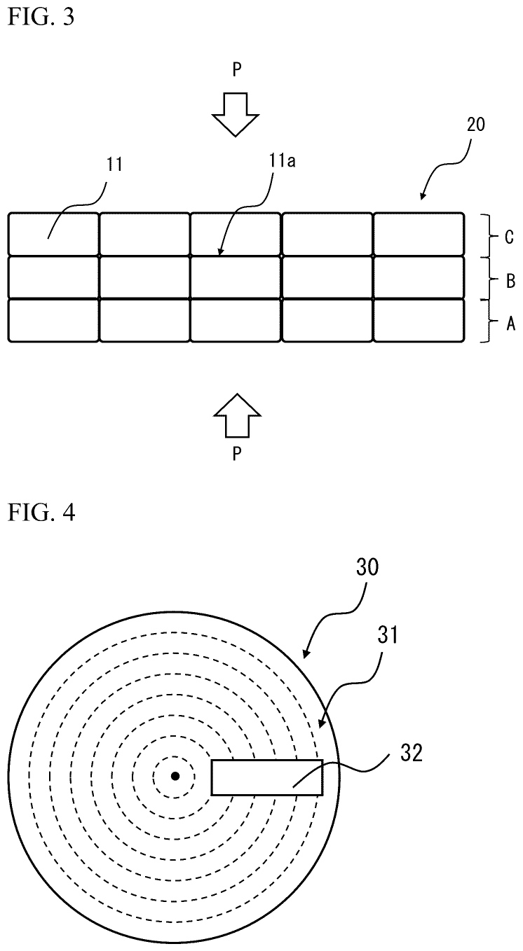

Here, as shown in the schematic cross-sectional diagram of FIG. 2, it is presumed that there is a void 12 between resin blocks 11 arranged adjacently, and the contact area of contact surfaces 11a between the resin blocks 11 is limited, resulting in insufficient fusion of the resin blocks 11. In this description, one section is shown in schematic cross-sectional diagrams shown in FIG. 2 and FIG. 3, which will be described later (in FIG. 2, the section is shown as one circle, and in FIG. 3, the section is shown as a substantially rectangular section) is referred to as a “resin block” for the purpose of explanation. However, the resin block may be a cross-section of one continuous arranged resin filament, or a cross-section of an arranged drop-shaped resin, and there are no particular limitation on the embodiment when the resin is arranged, and its cross-sectional shape. However, one resin block 11 shown in the schematic cross-sectional diagrams of FIG. 2 and FIG. 3 and the adjacent resin blocks 11 may have a slight difference in the time they were arranged, or, for example, it can be considered that they are extruded from different nozzles even when arranged simultaneously due to the use of a plural nozzles.

Next, a schematic cross-sectional diagram of an example of a compressed sheet obtained by the step P is shown in FIG. 3. More specifically, FIG. 3 shows a schematic cross-sectional diagram of an example of a compressed sheet 20 obtained by applying the pressure (p) to the sheet-shaped resin modeled article 10 formed by a 3D printer shown in FIG. 2 while heating with respect to the laminating direction (direction shown by an arrow P in FIG. 3) when the sheet-shaped resin modeled article 10 is formed by a 3D printer, and deforming the sheet-shaped resin modeled article 10.

In the step P, the direction of pressure applied to the sheet-shaped resin modeled article is not particularly limited as long as the effect of the present invention can be achieved. For example, similar to the direction indicated by the arrow P in FIG. 3, it is preferable to apply the pressure (p) in the thickness direction of the resin modeled article while heating. In addition, as shown in FIG. 3, it is more preferable to apply the pressure (p) in the thickness direction of the sheet-shaped resin modeled article, and the laminating direction (direction shown by the arrow P in FIG. 3) when forming a sheet-shaped resin modeled article with a 3D printer, while heating.

By performing the step P, that is, by applying the pressure (p) to a sheet-shaped resin modeled article formed by a 3D printer while heating, the sheet-shaped resin modeled article will be deformed. By the step P, as shown in FIG. 3, the void 12 that is present in FIG. 2 is reduced or eliminated, and also the contact area of the contact surfaces 11a of the mutually adjacent resin blocks 11 is increased. It is presumed that by heating and compressing the sheet-shaped resin modeled article, not only the contact area of the contact surfaces 11a between the resin blocks 11 increases, but also the entanglement of polymer molecules forming each resin block 11 also increases at the contact surfaces 11a between the resin blocks 11. It is presumed that these changes further promote the fusion of the resin blocks 11 and further increase the entanglement at the polymer molecular level, thereby significantly improving the mechanical properties of the finally obtained resin sheet.

Further, it is presumed that the significant improvement in the mechanical properties of the resin sheet obtained by the method for producing a resin sheet, which is one embodiment of the present invention, and the polishing layer described below is mainly due to an improvement in the contact area between the resin blocks and the increase in entanglement between the polymer molecules, as mentioned above. However, it is extremely difficult for the current technology to accurately evaluate the degree of contact area between resin blocks in the obtained entire resin sheet, and to further confirm the state of entanglement of polymer molecules between resin blocks and define the degree of entanglement.

Therefore, each of a resin sheet obtained using the method for producing a resin sheet, a polishing layer obtained using the method for producing a resin sheet, and a polishing pad having a polishing layer obtained by using the method for producing a resin sheet, is defined using the method for producing a resin sheet, which is one embodiment of the present invention. This is because there are circumstances which cannot avoid specifying by the method for producing a resin sheet.

The heating temperature in the step P is preferably higher than room temperature (23° C.), more preferably 60° C. or higher, even more preferably 80° C. or higher, even further preferably 90° C. or higher, even further preferably 100° C. or higher, even further preferably 110° C. or higher, even further preferably 120° C. or higher, from the viewpoint of making it easier to achieve the effects of the present invention.

The upper limit of the heating temperature is not particularly limited, however, for example, from the viewpoint of further preventing excessive compression of the resin sheet and thermal deterioration of the resin; and from the viewpoint of improving productivity; it is preferably 210° C. or lower, more preferably 200° C. or lower, even more preferably 190° C. or lower, even further preferably 180° C. or lower.

As described above, these lower limit value and upper limit value described in stages can be independently combined. For example, as one embodiment of the method for producing, the heating temperature in the step P is preferably 60 to 210° C., more preferably 80 to 200° C., even more preferably 90 to 200° C., even further preferably 100 to 190° C., even further preferably 110 to 190° C., even further preferably 120 to 180° C.

In one embodiment of the method for producing, the pressure (p) in the step P is preferably 0.1 MPa or more, more preferably 0.3 MPa or more, even more preferably 0.5 MPa or more, from the viewpoint of making it easier to achieve the effect of the present invention, and it is preferably 20 MPa or less, more preferably 15 MPa or less, even more preferably 10 MPa or less, from the viewpoint of further preventing excessive compression of the resin sheet; from the viewpoint of improving productivity; and the like.

As described above, these lower limit value and upper limit value described in stages can be independently combined. For example, in one embodiment of the method for producing, the pressure (p) in the step P is preferably 0.1 to 20 MPa, more preferably 0.3 to 15 MPa, even more preferably 0.5 to 10 MPa.

Further, in one embodiment of the method for producing, time (t) for applying the pressure (p) in the step P is preferably 1 second or more, more preferably 5 seconds or more, even more preferably 8 seconds or more, even further preferably 10 seconds or more, from the viewpoint of making it easier to achieve the effects of the present invention, and it is preferably 10000 seconds or less, more preferably 5000 seconds or less, even more preferably 500 seconds or less, even further preferably 200 seconds or less, from the viewpoint of further preventing thermal deterioration of the resin; from the viewpoint of improving productivity, and the like.

As described above, these lower limit value and upper limit value described in stages can be independently combined. For example, in one embodiment of the method for producing, the time (t) for applying the pressure (p) in the step P is preferably 1 to 10000 seconds, more preferably 5 to 5000 seconds, even more preferably 8 to 500 seconds, even further preferably 10 to 200 seconds.

In one embodiment of the method for producing, from the viewpoint of making it easier to achieve the effects of the present invention, it is preferable that the product of the pressure (p) and the time (t) for applying the pressure (p) satisfies the following formula (i), in the step P.

5≤p×t≤5000[a unit of p is MPa, a unit of t is second] Formula (i):

The value calculated by the above formula (i) is more preferably 10 or more, even more preferably 13 or more, from the viewpoint of making it easier to achieve the effects of the present invention, and it is more preferably 4500 or less from the viewpoint of further preventing excessive compression of the resin sheet and thermal deterioration of the resin; from the viewpoint of improving productivity; and the like, it is even more preferably 4000 or less; even further preferably 2000 or less, even further preferably 1000 or less, even further preferably 500 or less, from the viewpoint of making it easier to achieve the effects of the present invention; from the viewpoint of improving productivity, and the like.

As described above, these lower limit value and upper limit value described in stages can be independently combined. For example, as one embodiment of the method for producing, the value calculated from the above formula (i) is more preferably 5 to 4500, even more preferably 10 to 4000, even further preferably 10 to 2000, even further preferably 10 to 1000, even further preferably 13 to 500.

Further, it is preferable to use a spacer having a thinner thickness than the resin modeled article before heat press in the step P, from the viewpoint of further preventing excessive compression of the resin sheet and thermal deterioration of the resin, from the viewpoint of making it easier to control the thickness of the obtained compressed sheet, and the like.

More specifically, for example, the heat press in the step P may be performed using a known press machine such as a heat press machine which heats an article by sandwiching between heated upper and lower flat heat plates while applying pressure, or a calender roll which applies pressure with heated rolls. It is preferable to use a heat press machine from the viewpoint of making it easier to control the heating time and applied pressure. When performing heat press, it is more preferable that a spacer is placed as an outer frame of the sheet-shaped resin modeled article formed by a 3D printer, the pressure (p) is applied to the sheet-shaped resin modeled article in the state in which the spacer is sandwiched with the sheet-shaped resin modeled article, while heating. By this manner, in the early stage of heat press, pressure is applied only to the resin modeled article and the thickness quickly becomes thin, and once the thickness of the resin modeled article becomes the same as the thickness of the spacer, no further compression is applied, resulting that a sheet with a predetermined thickness can be easily obtained.

Further, as described above, when the spacer is used in the step P, the spacer which is in the state of independent from the heat press machine, may be prepared and used, or it may be used in the state of installed in advance in a press section of the heat press machine.

Furthermore, the shape of the spacer is not particularly limited as long as it can be used as an outer frame of the sheet-shaped resin modeled article formed by a 3D printer, as described above, and the examples include a circular ring-shaped one, or one whose outer edge is square and whose inner edge is circular or square.

Further, the thickness of the spacer is not particularly limited as long as the effect of the present invention is achieved, but it is preferably equal to or less than the thickness of the sheet-shaped resin modeled article before applying pressure, and preferably less than the thickness of the sheet-shaped resin modeled article before applying pressure. In addition, as one embodiment of the spacer, the ratio of the thickness (unit: mm) of the spacer to the thickness (unit: mm) of the sheet-shaped resin modeled article before applying pressure [thickness of a spacer/thickness of a sheet-shaped resin modeled article before applying pressure] is preferably 1.0 or less, more preferably less than 1.0, even more preferably 0.9 or less, and it is preferably 0.3 or more, more preferably 0.5 or more, even more preferably 0.7 or more.

As described above, these lower limit value and upper limit value described in stages can be independently combined. For example, as one embodiment of the method for producing, the ratio [thickness of a spacer/thickness of a sheet-shaped resin modeled article] is preferably 0.3 or more and 1.0 or less, more preferably 0.5 or more and less than 1.0, even more preferably 0.7 or more and 0.9 or less.

The spacer is preferably one that has removability with respect to the resin modeled article, and the examples include a spacer which is formed by at least one selected from the group consisting of fluororesins such as polytetrafluoroethylene and ethylenetetrafluoroethylene copolymer, epoxy resins, glass epoxy resins, and polyimide resins. Further, as one embodiment of the method for producing a resin sheet, for example, when the thermoplastic polyurethane is used as a resin forming the resin modeled article, it is preferable to use a spacer made of polytetrafluoroethylene.

In addition, from the viewpoint of making it easier to achieve the effect of the present invention, it is preferable that the step P is performed under a reduced pressure atmosphere.

The reason why the effect of the present invention is more easily achieved by performing the step P under a reduced pressure atmosphere is presumed that it becomes easier to remove air bubbles and voids left in the resin modeled article, and for example, it becomes easier to increase the contact area of the contact surface 11a between the resin blocks 11 in FIG. 3.

The degree of vacuum in the step P under the reduced pressure atmosphere is preferably 101 kPa or less, more preferably 50 kPa or less, even more preferably 10 kPa or less, even further preferably 5 kPa or less, in terms of absolute pressure. The degree of vacuum in the step P under the reduced pressure atmosphere is 0 kPa or more in terms of absolute pressure, and preferably 1 kPa or more from the viewpoint of cost reduction during manufacturing. In other words, in one embodiment of the method for producing, the degree of vacuum in the step P under the reduced pressure atmosphere is preferably 0 to 101 kPa, more preferably 0 to 50 kPa, even more preferably 0 to 10 kPa, even further preferably 0 to 5 kPa, even further preferably 1 to 5 kPa, in terms of absolute pressure.

### (Resin)

The resin which is the raw material for the resin modeled article in the step P may be a thermoplastic resin or a thermosetting resin as long as it can be formed by a 3D printer, and there are no particular limitations, however, thermoplastic resin is preferable.

Examples of the thermoplastic resin include, polyurethane; polyolefin resins such as polyethylene, polypropylene, polybutene, or copolymers polymerized from two or more selected from ethylene, α-olefins, cyclic olefins, vinyl acetate, styrene; olefin thermoplastic elastomer (TPO); polyvinyl chloride; polyvinyl acetate; styrene resins such as polystyrene and acrylonitrile styrene copolymers; acrylic resin such as a copolymer polymerized from one or more selected from methacrylic acid, methacrylic ester, acrylic ester, styrene; polyester resins such as polyethylene terephthalate, polybutylene terephthalate, and polylactic acid; polyester thermoplastic elastomer; polyamides such as aliphatic polyamides, alicyclic polyamides, and aromatic polyamides; polyamide thermoplastic elastomers; polycarbonate; silicone elastomers such as silicone rubber; polylactic acid; natural rubber; diene rubber which is a copolymer of one or more types selected from polybutadiene, polyisoprene, polychloroprene, or diene monomers such as butadiene, isoprene, and chloroprene, and one or more types of vinyl monomers such as styrene, ethylene, propylene, various butene, styrene, and acrylonitrile; acrylic acid alkyl ester rubber (acrylic rubber), which is a copolymer containing acrylic ester as the main monomer; fluorine resins such as polytetrafluoroethylene; and fluorine-based thermoplastic elastomer. These may be used alone or in combination of two or more.

Examples of the thermosetting resin include epoxy resin, thermosetting polyurethane, and thermosetting acrylic resin.

### ((Thermoplastic Polyurethane))

As one embodiment of the method for producing a resin sheet, the resin modeled article in the step P is preferably a modeled article of polyurethane, and more preferably a modeled article of thermoplastic polyurethane.

The thermoplastic polyurethane is not particularly limited as long as the effects of the present invention are achieved, however, for example, from the viewpoint of ease of manufacturing the thermoplastic polyurethane, it is preferable that at least structural a unit derived from polyols and a structural unit derived from polyisocyanate, and a structural unit derived from a chain extender are contained, and it is more preferable that it contains only a structural unit derived from a polyol, a structural unit derived from a polyisocyanate, and a structural unit derived from a chain extender.

The total content of the structural unit derived from polyol, the structural unit derived from polyisocyanate, and the structural unit derived from a chain extender, with respect to the total structural units in the thermoplastic polyurethane, is preferably 80% by mass or more, more preferably 85% by mass or more, even more preferably 90% by mass or more, even further preferably 95% by mass or more, even further preferably 100% by mass. In other word, in one embodiment of the method for producing, the total content of the structural unit derived from polyol, the structural unit derived from polyisocyanate, and the structural unit derived from chain extender, with respect to the total structural units in the thermoplastic polyurethane is preferably 80 to 100% by mass, more preferably 85 to 100% by mass, even more preferably 90 to 100% by mass, even further preferably 95 to 100% by mass, even further preferably 100% by mass.

### [Polyol]

Examples of the polyol include polymer diols such as polyether diols such as polyethylene glycol (PEG) and polytetramethylene ether glycol (PTMG); polyester diol; and polycarbonate diol. These may be used alone or in combination of two or more.

Among these, from the viewpoint of ease of availability and excellent reactivity, one or more selected from the group consisting of polyether diol and polyester diol is preferable. When the resin modeled article is used as a polishing layer of a polishing pad described later, it is preferable that at least one selected from the group consisting of a polyether diol which is selected from polyethylene glycol and polytetramethylene ether glycol; a polyester diol which is selected from poly(nonamethylene adipate), poly(2-methyl-1,8-octamethylene adipate), poly(2-methyl-1,8-octamethylene-co-nonamethylene adipate), poly(methylpentane adipate); and derivatives thereof, from the viewpoint of excellent hydrophilicity.

The number average molecular weight of the polyol is preferably 450 to 3,000, more preferably 500 to 2,700, even more preferably 550 to 2,400, even further preferably 650 to 1,400, even further preferably 800 to 1,200. When the number average molecular weight of the polyol is within the above range, a polishing layer with good properties such as rigidity, hardness, and hydrophilicity can be easily obtained, in the case of using the resin modeled article as a polishing layer to be described later, therefore, it is preferred. Note that the number average molecular weight of the polyol means a number average molecular weight calculated based on the hydroxyl value measured in accordance with JIS K 1557-1:2007.

### {Polyether Diol}

Examples of the polyether diol include, polyethylene glycol, polypropylene glycol, polytetramethylene ether glycol, poly(methyltetramethylene ether)glycol, glycerin-based polyalkylene ether glycol. These may be used alone or in combination of two or more.

Among these, polyethylene glycol (PEG), polytetramethylene ether glycol (PTMG) are preferable.

### {Polyester Diol}

Examples of the polyester diol include polyester diols obtained by directly esterifying or transesterifying a dicarboxylic acid or an ester-forming derivative, such as its ester or anhydride, and a low-molecular diol.

Examples of the dicarboxylic acid include, aliphatic dicarboxylic acids having 2 to 12 carbon atoms such as oxalic acid, succinic acid, glutaric acid, adipic acid, pimelic acid, suberic acid, azelaic acid, sebacic acid, dodecanedicarboxylic acid, 2-methylsuccinic acid, 2-methyladipic acid, 3-methyladipic acid, 3-methylpentanedicarboxylic acid 2-methyloctanedioic acid, 3,8-dimethyldecanedioic acid, and 3,7-dimethyldecanedioic acid; aliphatic dicarboxylic acids such as dimerized aliphatic dicarboxylic acids(dimer acids) having 14 to 48 carbon atoms obtained by dimerizing unsaturated fatty acids obtained by fractional distillation of triglycerides, and hydrogenated products thereof (hydrogenated dimer acids); alicyclic dicarboxylic acids such as 1,4-cyclohexanedicarboxylic acid; and aromatic dicarboxylic acids such as terephthalic acid, isophthalic acid, orthophthalic acid. These may be used alone or in combination of two or more.

Examples of the low-molecular diol include aliphatic diols such as ethylene glycol, 1,3-propanediol, 1,2-propanediol, 2-methyl-1,3-propanediol, 1,4-butanediol, neopentyl glycol, 1,5-pentanediol, 3-methyl-1,5-pentanediol, 1,6-hexanediol, 1,7-heptanediol, 1,8-octanediol, 2-methyl-1,8-octanediol, 1,9-nonanediol, and 1,10-decanediol; and alicyclic diols such as cyclohexanedimethanol and cyclohexanediol. These may be used alone or in combination of two or more. Among these, diols having 6 to 12 carbon atoms are preferred, diols having 8 to 10 carbon atoms are more preferred, diols having 9 carbon atoms are even more preferred.

### {Polycarbonate Diol}

Examples of the polycarbonate diol include what is obtained by a reaction of low-molecular diols and carbonate compounds. Examples of the low-molecular diol for producing polycarbonate diol include the above-described low-molecular diols.

Examples of the carbonate compounds for producing polycarbonate diol include dialkyl carbonate, alkylene carbonate, and diaryl carbonate.

Examples of the dialkyl carbonate include dimethyl carbonate, and diethyl carbonate, examples of the alkylene carbonate include ethylene carbonate, and examples of the diaryl carbonate include diphenyl carbonate.

### {Polyisocyanate}

As the polyisocyanate, it is not limited as long as it is polyisocyanate which is used for producing the usual thermoplastic polyurethane, and the examples include aliphatic or alicyclic diisocyanates such as ethylene diisocyanate, tetramethylene diisocyanate, pentamethylene diisocyanate, hexamethylene diisocyanate, 2,2,4-trimethylhexamethylene diisocyanate, 2,4,4-trimethylhexamethylene diisocyanate, dodecamethylene diisocyanate, isophorone diisocyanate, isopropylidene bis(4-cyclohexyl isocyanate), cyclohexylmethane diisocyanate, methylcyclohexane diisocyanate, 4,4′-dicyclohexylmethane diisocyanate, lysine diisocyanate, 2,6-diisocyanatomethyl caproate, bis(2-isocyanatoethyl) fumarate, bis(2-isocyanatoethyl) carbonate, 2-isocyanatoethyl-2,6-diisocyanatohexanoate, cyclohexylene diisocyanate, methylcyclohexylene diisocyanate, and bis(2-isocyanatoethyl)-4-cyclohexene; and aromatic diisocyanates such as 2,4′-diphenylmethane diisocyanate, 4,4′-diphenylmethane diisocyanate (MDI), 2,4-tolylene diisocyanate, 2,6-tolylene diisocyanate, m-phenylene diisocyanate, p-phenylene diisocyanate, m-xylylene diisocyanate, p-xylylene diisocyanate, 1,5-naphthylene diisocyanate, 4,4′-diisocyanatobiphenyl, 3,3′-dimethyl-4,4′-diisocyanatobiphenyl, 3,3′-dimethyl-4, 4′-diisocyanatodiphenylmethane, chlorophenylene-2,4-diisocyanate, and tetramethylxylylene diisocyanate. These may be used alone or in combination of two or more.

Among these, when the resin modeled article is used for the polishing layer of the polishing pad described later, 4,4′-diphenylmethane diisocyanate (MDI) is preferable, from the viewpoint of improving the abrasion resistance of the obtained polishing layer.

### [Chain Extender]

As the chain extender, any chain extenders which are conventionally used in the production of the usual thermoplastic polyurethane may be used. Specifically, it is preferably use a low molecular weight compound having molecular weight of 300 or less and having 2 or more of active hydrogen atoms which may react with the isocyanate group in a molecule, and the examples include, diols such as ethylene glycol, diethylene glycol (DEG), 1,2-propanediol, 1,3-propanediol, 2,2-diethyl-1,3-propanediol, 2,2,4-trimethyl-1,3-propanediol, 2-butyl-2-ethyl-1,3,-propanediol, 1,2-butanediol, 1,3-butanediol, 2,3-butanediol, 1,4-butanediol (BD), 1,5-pentanediol (PD), neopentyl glycol, 1,6-hexanediol, 2,5-dimethyl-2,5-hexanediol, 3-methyl-1,5-pentanediol (MPD), 1,4-bis(μ-hydroxyethoxy)benzene, 1,4-cyclohexanediol, cyclohexanedimethanol(1,4-cyclohexanedimethanol etc.), bis(β-hydroxyethyl)terephthalate, 1,9-nonanediol (ND), m-xylylene glycol, p-xylylene glycol, triethylene glycol; and diamines such as ethylenediamine, trimethylenediamine, tetramethylenediamine, hexamethylenediamine, heptamethylenediamine, octamethylenediamine, nonamethylenediamine, decamethylenediamine, undecamethylenediamine, dodecamethylenediamine, 2,2,4-trimethylhexamethylenediamine, 2,4,4-trimethylhexamethylenediamine, 3-methylpentamethylenediamine, 1,2-cyclohexanediamine, 1,3-cyclohexanediamine, 1,4-cyclohexanediamine, 1,2-diaminopropane, 1,3-diaminopropane, hydrazine, xylylenediamine, isophoronediamine, piperazine, o-phenylenediamine, m-phenylenediamine, p-phenylenediamine, tolylenediamine, xylenediamine, adipic acid dihydrazide, isophthalic acid dihydrazide, 4,4′-diaminodiphenylmethane, 4,4′-diaminodiphenyl ether, 4,4′-bis(4-aminophenoxy)biphenyl, 4,4′-bis(3-aminophenoxy)biphenyl, 1,4-bis(4-aminophenoxy)benzene, 1,3-bis(4-aminophenoxy)benzene, 1,3-bis(3-aminophenoxy)benzene, 3,4′-diaminodiphenyl ether, 4,4′-diaminodiphenylsulfone, 3,4-diaminodiphenylsulfone, 3,3′-diaminodiphenylsulfone, 4,4′-methylene-bis(2-chloroaniline), 3,3′-dimethyl-4,4′-diaminobiphenyl, 4,4′-diaminodiphenyl sulfide, 2,6-diaminotoluene, 2,4-diaminochlorobenzene, 1,2-diaminoanthraquinone, 1,4-diaminoanthraquinone, 3,3′-diaminobenzophenone, 3,4-diaminobenzophenone, 4,4′-diaminobenzophenone, 4,4′-diaminobibenzyl, 2,2′-diamino-1,1′-binaphthalene, 1,n-bis(4-aminophenoxy)alkanes (n is 3 to 10) such as 1,3-bis(4-aminophenoxy)alkane, 1,4-bis(4-aminophenoxy)alkane, 1,5-bis(4-aminophenoxy)alkane; 1,2-bis[2-(4-aminophenoxy)ethoxy]ethane, 9,9-bis(4-aminophenyl)fluorene, and 4,4′-diaminobenzanilide. These may be used alone or in combination of two or more.

Among these, at least one selected from the group consisting of 1,3-propanediol, 1,4-butanediol (BD), neopentyl glycol, 1,5-pentanediol (PD), 1,6-hexanediol, and cyclohexane dimethanol is preferred.

The blending ratio of each component of a monomer polyol used in the polymerization of the thermoplastic polyurethane, polyisocyanate, and a chain extender is appropriately selected in consideration of the desired physical properties such as abrasion resistance. For example, from the viewpoint of being excellent in mechanical strength, abrasion resistance, productivity, and storage stability of thermoplastic polyurethane, the ratio of isocyanate group contained in polyisocyanate is preferably 0.80 to 1.30 moles, more preferably 0.85 to 1.20 moles, even more preferably 0.90 to 1.10 moles, even further preferable 0.95 to 1.05 moles, with respect to 1 mole of active hydrogen atoms contained in polyol and a chain extender. It is preferred since when the ratio is 0.80 or more, the mechanical properties of the resin modeled article formed from the thermoplastic polyurethane tend to be further improved, and when it is 1.30 mole or less, the productivity and storage stability of the thermoplastic polyurethane tend to be further improved.

As for the mass ratio of polyol, polyisocyanate, and a chain extender, [amount of polyol/(total amount of polyisocyanate and a chain extender)] is preferably 10/90 to 50/50, more preferably 15/85 to 45/55, even more preferably 20/80 to 40/60.

### [Method for Producing Thermoplastic Polyurethane]

The thermoplastic polyurethane can be obtained by polymerization using the above-described raw materials by a urethanization reaction using the known prepolymer method or the known one-shot method. More specifically, the examples include a method by melt polymerization in which the above-described each component is blended in a predetermined ratio and melt-mixed using a single-screw or multi-screw extruder to produce in substantially absence of a solvent (Continuous melt polymerization method); and a method by polymerization to produce using a prepolymer method in the presence of a solvent.

The nitrogen content ratio derived from the isocyanate group of the polyisocyanate of the thermoplastic polyurethane is preferably 4.0 to 8.0% by mass, more preferably 4.5 to 7.5% by mass, even more preferably 5.0 to 7.0% by mass.

Note that the nitrogen content ratio means “(mass ratio of structural units derived from polyisocyanate contained in thermoplastic polyurethane)×((total mass of nitrogen atoms present in isocyanate groups contained in one molecule of polyisocyanate)/(mass of one molecule of polyisocyanate))×100”, and it can be measured based on the methods described below.

First, the total nitrogen content is calculated by elemental analysis method under the following conditions.
Device: fully automatic elemental analyzer 2400 series II type (automatic sampler standard equipment) C·H·N·S/O analyzer, manufactured by PerkinElmer Inc.
Electric furnace temperature: 975° C.
Sample amount: 2 mg
Combustion improver: None
Sample container: Tin foil (having a combustion assisting effect, 1 sheet is used)
Standard material for preparing a calibration curve: sulfanilamide
Next, nitrogen atoms derived from the polyisocyanate and nitrogen atoms derived from the chain extender are detected by NMR measurement under the following conditions.
Device: nuclear magnetic resonance device Lambda500, manufactured by JEOL Ltd.
Measurement conditions: Resonance frequency: 1H 500 MHz/probe; TH5FG2
Solvent: DMSO-d6 Concentration; 5 wt %/vol
Measurement temperature: 80° C.
Accumulation count: 64 s

Then, the nitrogen content ratio derived from the isocyanate groups of the polyisocyanate is calculated from the results of elemental analysis and NMR.

### ((Additive))

The resin may contain additives such as crosslinking agent, filler, crosslinking accelerator, crosslinking aid, softener, tackifier, anti-aging agent, foaming agent, processing aid, adhesion agent, inorganic filler, organic filler, crystal nucleating agent, heat-resistant stabilizer agents, weathering stabilizers, antistatic agents, colorants, lubricants, flame retardants, flame retardant aids (antimony oxide, and the like), anti-blooming agents, mold release agents, thickeners, antioxidants, conductive agents, as needed.

When the resin contains additives, the total content of the additives in the resin is not particularly limited, however it is preferably 50% by mass or less, more preferably 20% by mass or less, even more preferably 10% by mass or less, even further preferably 5% by mass or less. Further, when the resin contains additives, the lower limit value of the total content of the additives in the resin is not particularly limited, however, for example, it is preferably 0.01% by mass.

As described above, these lower limit value and upper limit value described in stages can be independently combined. As one embodiment of the method for producing, for example, the total content of these additives in the resin is preferably 0.01 to 50% by mass, more preferably 0.01 to 20% by mass, even more preferably 0.01 to 10% by mass, even further preferably 0.01 to 5% by mass.

### <Step M>

The step M is a step of discharging a melt or a precursor of resin from a nozzle and solidifying it to form a sheet-shaped resin modeled article, using a 3D printer.

It is preferable that the step M is a step of laminating a multiple layers by repeating discharging of a melt or a precursor of resin from a nozzle and solidifying of it, to form a sheet-shaped resin modeled article, using a 3D printer.

### (3D Printer)

A 3D printer is a device that can perform three-dimensional modeling using 3D printing technology which three-dimensionally shapes raw materials based on a blueprint of three-dimensional data such as 3D CAD or 3D CG. As the 3D printer which can be used in the step M, it is not particularly limited as long as it is at least a device which can form a sheet-shaped resin modeled article by discharging a melt or a precursor of resin from a nozzle and solidifying it. However, for example, it is preferable that a 3D printer which can form the sheet-shaped resin modeled article by a fused deposition modeling method (hereinafter, it will also simply be referred to as the “FDM method”) in which a modeled article is formed by being extruded of a melt or a precursor of the resin from a nozzle, and laminating one layer by one layer on a modeling table, is used.

There is no particular limitation on the direction in which the layers are arranged on the modeling table. For example, in the case of a rectangular resin sheet, the one layer can be formed by arranging the resin one row at a time and arranging them in multiple rows. Alternatively, for example, in the case of a disc-shaped resin sheet, the one layer may be formed by arranging the resin in a concentric pattern.

The 3D printer may be equipped with a single nozzle, or may be equipped with a plurality of nozzles. The nozzle is not particularly limited as long as it does not impair the effects of the present invention, however for example, a nozzle having a hole diameter at the tip of the nozzle preferably 0.1 to 10 mm, more preferably 0.3 to 7.0 mm, even more preferably 0.5 to 3.0 mm, can be used.

Further, the nozzle may discharge the melt or precursor of the resin while moving. The melt or precursor of the resin discharged from the nozzle is preferably discharged, for example, in the form of a filament or drop, and by the nozzle moving, the melt material is placed on a modeling table provided at the bottom of the nozzle at a position that has been previously indicated based on a blueprint of 3D data. Then, a sheet-shaped resin modeled article is formed by placing only one layer of the resin modeled article formed by the resin on the modeling table, or by laminating the sheets one layer by one layer from the lower layer to the upper layer.

Furthermore, as one embodiment of the step M, the resin modeled article may be formed while the nozzle is remained to be fixed, and the modeling table, on which the melt or precursor of the resin discharged from the nozzle is placed, is moved. Alternatively, the resin modeled article may be formed while both the nozzle and the modeling table are moved.

In addition, in the step M, from the viewpoint of preventing foreign matter from entering the resulting resin modeled article, it is preferable that the melt or precursor of the resin passes through a filter before being discharged from the nozzle of the 3D printer.

The filter is not particularly limited as long as it does not impair the effects of the present invention, and for example, filters made of metal, made of thermoplastic resin, or made of thermosetting resin can be used. Among these, filters made of metal are preferred from the viewpoint of the ability to be used even when the temperature of the melt or the precursor of the resin is higher and from the viewpoint of durability.

Examples of the filter made of metal include stainless steel wire (mesh) filters.

In addition, the filtration accuracy of the filter is preferably 200 μm or less, more preferably 150 μm or less, even more preferably 100 μm or less, even further preferably 50 μm or less, even further preferably 20 μm or less, from the viewpoint of more effectively preventing foreign matter from entering the resin modeled article.

Here, the above-mentioned “filtration accuracy of the filter” refers to the “nominal filtration accuracy”, and for example, “filtration accuracy of 100 μm or less” means that the filter is capable of removing 95% or more of particles with a particle size of 100 μm or more.

Further, the filter may be appropriately selected from the viewpoint of the type of foreign matter to be prevented from being mixed into the resin modeled article, productivity, and the like, and there is no particular limitation as long as it does not impair the effects of the present invention. However, as one embodiment of the filter, for example, it is preferably that a filter in which the vertical and horizontal mesh sizes is each independently 20 to 2800 mesh, and the vertical and horizontal wire diameters is each independently 20 to 200 μm, can be used.

The filter is installed before the resin melt or its precursor is discharged from the nozzle, and the installation location is not particularly limited as long as it does not impair the effects of the present invention. For example, the installation location of the filter is preferably to be installed in a flow path of the resin in the nozzle after the resin or resin precursor is supplied into the 3D printer and before it is discharged from the nozzle, from the viewpoint of more effectively preventing foreign matter from entering the resin modeled article, such as being able to remove foreign matter generated or mixed in after the resin or resin precursor is melted in the 3D printer.

In addition, in the step M, when the resin is a thermoplastic resin, the form in which the thermoplastic resin is supplied to the 3D printer is not particularly limited, however, for example, it may be the form of powder, pellets, and strands. In one embodiment of the step M, it is preferable that the thermoplastic resin is supplied to the 3D printer in the form of pellets. Furthermore, when supplying the thermoplastic resin to the 3D printer it is preferable that dry nitrogen with a dew point temperature of −30° C. or lower or dry air with a dew point temperature of −30° C. or lower is supplied to the 3D printer together with the pelletized thermoplastic resin. It is preferable that by supplying the thermoplastic resin in the form of pellets using this method, it is possible to further reduce molding defects and deterioration of the physical properties of resin modeled articles due to foaming, void formation, discoloration, decomposition, and the like, due to moisture absorption of the thermoplastic resin in the 3D printer, and it is also possible to more effectively prevent foreign matter from entering the resin modeled article, such as by suppressing the generation of foreign matter due to deterioration of the resin. From this viewpoint, the dew point temperatures of the dry nitrogen and the dry air are each independently more preferably −40° C. or lower, even more preferably −50° C. or lower. Further, it is preferable that the lower limit value of the dry nitrogen and the lower limit value of the dew point temperature of the dry air are each independently, for example, −100° C.

As described above, these lower limit value and upper limit value described in stages can be independently combined. For example, as one embodiment of the method for producing, the dew point temperatures of the dry nitrogen and dry air are each independently preferably −100° C. or higher and −30° C. or lower, more preferably −100° C. or higher and −40° C. or lower, and even more preferably −100° C. or higher and −50° C. or lower.

Further, from the same viewpoint, it is desirable to further reduce the moisture content in the thermoplastic resin, and it is preferable to perform dehumidification drying before supplying the thermoplastic resin to a 3D printer.

The resin in the step M may be a thermoplastic resin or a thermosetting resin as long as it can be formed by the 3D printer used in the step M, and there is no limitation, however, the thermoplastic resin is preferable.

In addition, when a precursor of the resin is used, after being discharged from a nozzle, it is transformed into a resin modeled article made of the resin. As a method for converting the precursor of the resin into a resin, for example, a method of forming a resin modeled article by increasing the molecular weight of a precursor through chemical reactions such as polymerization and crosslinking reactions using light irradiation and thermosetting methods.

Examples of the thermoplastic resin in the step M include those similar to the thermoplastic resins described above in the section of the step P, and the thermoplastic resins may be used alone or in combination of two or more.

As one embodiment of the step M, the resin in the step M is preferably polyurethane, and more preferably thermoplastic polyurethane. That is, the thermoplastic resin in the step M is more preferably thermoplastic polyurethane.

Examples of the thermoplastic polyurethane in the step M include those similar to the thermoplastic polyurethane described above in the section of the step P, and the same applies to preferred embodiments thereof.

Further, in the step M, the solidification of the resin may be performed by cooling, light irradiation, thermosetting, and the like. In one embodiment of the step M, it is preferable that the resin is a thermoplastic resin and the solidifying of the thermoplastic resin is performed by cooling.

The method of cooling is not particularly limited, and may be natural cooling, or forced cooling by cooling the modeling table, blowing cold air onto the resin modeled article, or the like, however, natural cooling is preferable.

When the method for producing a resin sheet includes the step M, the step M is a step performed before the step P as described above.

In one embodiment of the method for producing a resin sheet, the sheet-shaped resin modeled article obtained in the step M may be a sheet-shaped resin modeled article obtained by performing the step M one time, or may be a sheet-shaped resin modeled article obtained by performing the step M multiple times. When performing the step M multiple times, the sheet-shaped resin modeled article may be a multi-layer sheet-shaped resin modeled article made of different resins (a laminate formed from sheet-shaped resin modeled article). Further, in this case, it may be a laminate in which a plurality of sheet-shaped resin modeled article obtained in the plurality of the steps M are laminated on each other via another layer such as an adhesive layer. Further, for example, it may be a sheet-shaped resin modeled article obtained by continuously or discontinuously changing the type of the resin or precursor of the resin, when obtaining one sheet-shaped resin modeled article in one step M.

Further, as one embodiment of the method for producing a resin sheet, the sheet-shaped resin modeled article obtained in the step M may be used as it is as the sheet-shaped resin modeled article in the step P. From the viewpoint of reducing the number of steps, it is preferable to use the sheet-shaped resin modeled article obtained in the step M as it is as the sheet-shaped resin modeled article in the step P.

In addition, as one embodiment of the method for producing a resin sheet, a laminate obtained by laminating the sheet-shaped resin modeled article obtained in the step M and a resin sheet, and the like, manufactured by another producing method may be used as the sheet-shaped resin modeled article in the step P. In this case, the sheet-shaped resin modeled article in the step M may be formed by directly laminating it on the surface of a resin sheet, and the like, manufactured by another producing method by the method of the step M. It also may be a laminate in which the sheet-shaped resin modeled article obtained in the step M and a resin sheet, and the like, manufactured by another producing method are laminated on each other via another layer such as an adhesive layer.

In addition, as one embodiment of the method for producing a resin sheet, the sheet-shaped resin modeled article obtained in the step M or each of the above-mentioned laminates may be used as a sheet-shaped resin modeled article in the step P, by processing into the desired shape using one or more methods selected from the group consisting of cutting, machining, grinding, and punching, before performing the step P.

Further, as one embodiment of the method for producing a resin sheet, when the resin modeled article obtained in the step M or each of the above-mentioned laminates is used as the sheet-shaped resin modeled article in the step P, the thickness of the sheet-shaped resin modeled article can be appropriately set depending on the use of the sheet obtained through the step P, however it is preferably 0.5 to 15 mm, more preferably 1.0 to 10 mm, even more preferably 1.5 to 5.0 mm.

### <Step T>

The step T is a step of making the thickness of the compressed sheet obtained in the step P thin using one or more methods selected from the group consisting of cutting, machining, and grinding.

When the step T is included as one embodiment of the method for producing a resin sheet, this is preferable since it becomes easier to adjust the thickness of the resulting resin sheet to a more uniform thickness.

As the above-mentioned cutting, machining, and grinding methods, known methods for processing a resin modeled article can be used.

### <Other Steps>

One embodiment of the method for producing a resin sheet may include other steps in addition to the steps described above.

As other steps include, for example, there may be a step C after the step P or, when the step T is included, there may be the step C between the step P and the step T. The step C is a cooling press step which is a cooling step of sandwiching and cooling while applying pressure between upper and lower flat plates and having lower temperature. When the cooling step is included, the heating press (step P) and the cooling press (step C) may be performed in sequence with one heat press machine, or the heating press (step P) and the cooling press (step C) may be performed using separate press machine. The temperature during the cooling press is preferably 55° C. or lower, more preferably −50 to 50° C., even more preferably 0 to 45° C., even further preferably 10 to 40° C. The pressure during the cooling press is preferably 0.01 to 10 MPa, more preferably 0.05 to 5 MPa, even more preferably 0.1 to 3 MPa, even further preferably 0.2 to 1 MPa.

When the step C is included, by cooling the sheet-shaped resin modeled article heated in the step P while keeping it flat, deformation of the resin modeled article that has become soft due to heating can be prevented, and the resin modeled article is not at a high temperature, therefore it is preferable from the viewpoint that it can be quickly sent to the next step.

### <Resin Sheet Obtained by the Method for Producing>

The thickness of the resin sheet (hereinafter also simply referred to as a “sheet”) obtained by the above method for producing can be set as appropriate depending on the use of the sheet, however as one embodiment of the sheet, it is preferably 0.5 to 5.0 mm, more preferably 1.0 to 3.0 mm, even more preferably 1.2 to 2.5 mm.

In one embodiment of the resin sheet, the storage modulus of the resin sheet measured under conditions of a temperature of 21° C., a frequency of 11 Hz, and a tensile condition is preferably 250 MPa or more, more preferably 400 to 4000 MPa, even more preferably 600 to 3000 MPa.

In one embodiment of the resin sheet, the breaking stress of the resin sheet measured under conditions of a temperature of 23° C., a tensile speed of 500 mm/min, is preferably 15 MPa or more, more preferably 30 to 90 MPa, even more preferably 35 to 70 MPa.

More specifically, the storage modulus and breaking stress values of the resin sheet are measured by the method described in the Examples below.

The use of the sheet obtained by the method for producing is not particularly limited, but it is preferably a polishing layer used in a polishing pad described below. That is, the resin sheet obtained by the method for producing is preferably a polishing layer for a polishing pad.

### [Polishing Pad]

A polishing pad that is one embodiment of the present invention has a polishing layer obtained using the method for producing a resin sheet that is one embodiment of the present invention.

As the polishing layer of the polishing pad, the sheet obtained by the method for producing may be used as it is, or a sheet obtained by further processing the sheet obtained by the method for producing into a desired sheet shape using one or more methods selected from the group consisting of cutting, machining, grinding, and punching, may be used.

Further, the polishing layer is more preferably a polishing layer formed using the above-mentioned thermoplastic polyurethane as the resin, and may be either a foamed or non-foamed material of the thermoplastic polyurethane, however it is even more preferably a non-foamed material. When the polishing layer is a non-foamed material of the thermoplastic polyurethane, the polishing uniformity of the polishing pad having the polishing layer becomes high, and it is possible to further suppress the variation by the foaming distribution and the occurrence of the defects derived due to the aggregates in the foaming, allowing that the stable polishing in which the polishing properties are less prone to fluctuate, can be achieved.

Further, the density of the polishing layer formed using the thermoplastic polyurethane is preferably 0.75 g/cm³ or more, more preferably 0.85 g/cm³ or more, even more preferably 1.0 g/cm³ or more, even further preferably is 1.1 g/cm³ or more. When the density is the above-described lower limit value or more, the polishing layer has appropriate flexibility. Further, the upper limit of the density is not particularly limited, however, for example, it is preferably 1.3 g/cm³.

As described above, these lower limit value and upper limit value described in stages can be independently combined. For example, as one embodiment of the polishing layer, the density of the polishing layer is preferably 0.75 to 1.3 g/cm³, more preferably 0.85 to 1.3 g/cm³, even more preferably 1.0 to 1.3 g/cm³, even further preferably is 1.1 to 1.3 g/cm³.

Further, when the polishing layer formed by using the thermoplastic polyurethane is a polishing layer formed by using a non-foamed thermoplastic polyurethane, it is preferable from the view point of its excellent in polishing stability due to its higher rigidity and the uniformity of the material.

The shape of the polishing layer is not particularly limited, and examples thereof include a circular shape, in a plan view. As described above, for example, the shape of the polishing layer may be formed directly during forming with a 3D printer by considering the compression ratio in the step P when forming by the method for producing a resin sheet and designing in advance by a 3D data. Alternatively, as described above, the resin modeled article obtained by the method for producing can be further appropriately prepared by one or more types of processing selected from the group consisting of cutting, machining, grinding, and punching, or the like.

A thickness of the polishing layer is not particularly limited, however, it is preferably 0.5 to 5.0 mm, more preferably 1.0 to 3.0 mm, even more preferably 1.2 to 2.5 mm. When the thickness of the polishing layer is within the above-described range, it is preferable since the productivity and handling properties are improved, and the stability of the polishing properties is also improved.

Further, it is preferable that recesses such as grooves and holes are formed on the polished surface of the polishing layer in a predetermined pattern such as concentric, lattice, spiral, and radial patterns. Such recesses supply slurry uniformly and sufficiently to the polished surface, and are useful for discharging polishing debris that causes scratches and preventing damage to a wafer due to adsorption of the polishing layer. For example, when forming a groove in a concentric circles shape, the interval (pitch) between the grooves is preferably 1.0 to 50 mm, more preferably 1.5 to 30 mm, even more preferably 2.0 to 15 mm. Further, the width of the groove is preferably 0.1 to 3.0 mm, more preferably 0.2 to 2.0 mm. Furthermore, the depth of the groove is less than the thickness of the polishing layer, and it is preferably 0.2 to 1.8 mm, more preferably 0.4 to 1.5 mm. In addition, as a cross-sectional shape of the groove, it is appropriately selected, for example, from a rectangle, a trapezoid, a triangle, and a semicircle, depending on the purpose.

The recesses on the polished surface may be formed directly during forming with a 3D printer by designing in advance by a 3D data when forming by the method for producing a resin sheet. Alternatively, the recesses may be formed by methods such as by grinding processing, laser processing, transfer using a mold and the like, and stamping with a heated mold on the resin modeled article obtained by the method for producing a resin modeled article.

The hardness of the polishing layer is such that the D hardness value measured according to JIS K 7311:1995 is preferably 45 or more, more preferably 50 or more, even more preferably 55 or more, and preferably 90 or less, more preferably 85 or less, even more preferably 80 or less.

As described above, these lower limit value and upper limit value described in stages can be independently combined. For example, as one embodiment of the polishing layer, the D hardness value of the polishing layer is preferably 45 to 90, more preferably 50 to 85, even more preferably 55 to 80.

In one embodiment of the polishing layer, the wear rate of the polishing layer evaluated by the method described in the Examples below is preferably 100 μm/hr or less, more preferably 90 μm/hr or less, even more preferably 75 μm/hr, even further preferably 60 μm/hr or less. Further, the lower limit value of the wear rate is not particularly limited, however, for example, it is preferably 10 μm/hr.

As described above, these lower limit value and upper limit value described in stages can be independently combined. For example, as one embodiment of the polishing layer, the wear rate of the polishing layer is preferably 10 to 100 μm/hr, more preferably 10 to 90 μm/hr, even more preferably 10 to 75 μm/hr, even further preferably is 10 to 60 μm/hr.

The polishing pad may consist only of the polishing layer obtained by the method for producing a resin sheet which is one embodiment of the present invention, or may be a laminate in which a cushion layer is laminated on the surface which is not a polished surface of the polishing layer.

The cushion layer preferably has a hardness lower than that of the polishing layer. When the hardness of the cushion layer is lower than the hardness of the polishing layer, it is preferable since the rigid polishing layer follows local unevenness on the surface to be polished, and the cushion layer becomes easier to follow the warping and swelling of the entire substrate to be polished, therefore, the polishing with an further excellent balance between global planarity (a state in which unevenness of wafer substrate having large cycles is reduced) and local planarity (a state in which local unevenness is reduced) can be achieved.

As a thickness of the cushion layer, it is not particularly limited, however, for example, it is preferably 0.3 to 5.0 mm.

Examples of materials used as the cushion layer include composites of nonwoven fabric impregnated with polyurethane (for example, “Suba (registered trademark) 400” (manufactured by Nitta Haas Incorporated.)); rubbers such as natural rubber, nitrile rubber, polybutadiene rubber, and silicone rubber; thermoplastic elastomers such as polyester-based thermoplastic elastomers, polyamide-based thermoplastic elastomers, and fluorine-based thermoplastic elastomers; foamed plastics; and polyurethane.

Among these, the polyurethane having a foamed structure is particularly preferred since the suitable flexibility for the cushion layer is easily obtained.

Note that the polyurethane in the description regarding the cushion layer includes both thermoplastic polyurethane and thermosetting polyurethane.

The polishing layer and the cushion layer may be laminated to each other using, for example, double-sided tape, or may be laminated to each other via an adhesive layer. Further, when forming the polishing layer by the method for producing a resin modeled article, it may be laminated by a method in which all or part of the polishing layer is formed directly onto the cushion layer or another intermediate layer (for example, an adhesive layer).

Since the polishing pad has a polishing layer obtained using the method for producing a resin modeled article, the abrasion resistance of the polishing layer can be improved. Therefore, by using a polishing pad having a polishing layer obtained using the method for producing a resin modeled article, it is possible to contribute to extending the life of the polishing pad.

Accordingly, for example, it can be suitably used as a polishing pad used in a polishing method for planarizing the surface of a semiconductor wafer, and can be used more suitably as a polishing pad for planarizing the surface of a semiconductor wafer by a CMP (Chemical Mechanical Polishing (Planarization)) polishing method. Note that CMP is a method of polishing an object to be polished with high accuracy using a polishing pad while supplying a slurry containing abrasive grains and a reaction solution to the surface of the object to be polished, and is known as a method suitable for polishing semiconductor materials and the like such as silicon wafer.

### EXAMPLE

Next, the present invention will be more specifically described by Examples, but the present invention is not limited to these Examples.

Each components used in Examples or Comparative examples will be described below with abbreviations.

### Production Example 1

Polytetramethylene ether glycol [abbreviation: PTMG] with a number average molecular weight of 850, 1,4-butanediol [abbreviation: BD], and 4,4′-diphenylmethane diisocyanate [abbreviation: MDI], were used in a ratio of PTMG:BD:MDI=32.5:15.6:51.9 (mass ratio), and continuously supplied with a metering pump to a coaxially rotating twin-screw extruder to perform continuous melt polymerization and thermoplastic polyurethane was produced. Then, the melt of polymerized thermoplastic polyurethane was continuously extruded into water in the form of a strand, and then shredded with a pelletizer to obtain thermoplastic polyurethane pellets. The pellets were dehumidified and dried at 70° C. for 20 hours, and then sealed in a moisture-proof bag.

### Example 1

To a 3D printer of the fused deposition modeling method, a stainless wire mesh having a filtration accuracy of 70 μm (plain dutch weave, vertical mesh 50, horizontal mesh 250, vertical wire diameter 140 μm, horizontal wire diameter 110 m) is installed in a resin flow path in a nozzle (tip hole diameter 1 mm), the thermoplastic polyurethane pellets obtained in Production Example 1 is supplied together with dry air with a dew point temperature of −60° C., and formed into a disc shape having a diameter of 40 cm in a concentric pattern, and five layers are laminated thereon in the same manner (six layers in total) to obtain a disc-shaped sheet with a thickness of 3 mm and a diameter of 40 cm.

Next, a pressure of 3 MPa was uniformly applied from above the sheet surface under a reduced pressure atmosphere with a degree of vacuum of 3 kPa using a vacuum heat press (that is, evenly applied in the thickness direction of the disc-shaped sheet and in the laminating direction when the disc-shaped sheet is formed by the 3D printer), and the sheet was processed at 140° C. for 2 minutes to obtain a compressed sheet. The product of the pressure (p) [MPa] and the time (t) [seconds] in this step is 360.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 713 MPa, 50 MPa, and 315%. The results are shown in Table 1 below.

Further, after cutting out the sheet having a thickness of 1.5 mm in a diameter of 38 cm, spiral grooves with a width of 1.0 mm, a depth of 0.8 mm, and a pitch of 3.5 mm were formed on the polished surface. Next, double-sided tape (“#5605HG”, manufactured by Sekisui Chemical Co., Ltd.) was attached to the back side, which is the side opposite to the polished surface, to produce a polishing pad. The wear rate of this polishing pad was evaluated using the method described below and was found to be 58 μm/hr. The results are shown in Table 1 below.

### Example 2

In the same manner as in Example 1, the thermoplastic polyurethane pellets obtained in Production Example 1 were supplied to a 3D printer to obtain a disc-shaped sheet having a thickness of 3 mm and a diameter of 40 cm.

Next, a pressure of 0.5 MPa was uniformly applied from above the sheet surface of the disc-shaped sheet under an atmospheric pressure atmosphere using a heat press, and the treatment was performed at 120° C. for 1 hour to obtain a compressed sheet. The product of the pressure (p) [MPa] and the time (t) [seconds] in this step is 1800.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 691 MPa, 43 MPa, and 216%. The results are shown in Table 1 below.

Further, in the same manner as in Example 1, a polishing pad was manufactured from the sheet having a thickness of 1.5 mm, and the wear rate was measured, and it was found to be 64 μm/hr. The results are shown in Table 1 below.

### Example 3

In the same manner as in Example 1, the thermoplastic polyurethane pellets obtained in Production Example 1 were supplied to a 3D printer to obtain a disc-shaped sheet having a thickness of 3 mm and a diameter of 40 cm.

Next, a spacer made of polytetrafluoroethylene with a thickness of 2.5 mm was placed as an outer frame of the disc-shaped sheet, and a pressure of 3 MPa was applied uniformly to the sheet surface of the disc-shaped sheet under a reduced pressure atmosphere with a degree of vacuum of 3 kPa using a vacuum heat press, and the treatment was performed at 1600 for 30 seconds to obtain a compressed sheet. The product of the pressure (p) [MPa] and the time (t) [seconds] in this step is 90.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 729 MPa, 56 MPa, and 323%. The results are shown in Table 1 below.

Further, in the same manner as in Example 1, a polishing pad was manufactured from the sheet having a thickness of 1.5 mm, and the wear rate was measured, and it was found to be 55 μm/hr. The results are shown in Table 1 below.

### Example 4

In the same manner as in Example 1, the thermoplastic polyurethane pellets obtained in Production Example 1 were supplied to a 3D printer to obtain a disc-shaped sheet having a thickness of 3 mm and a diameter of 40 cm.

Next, a pressure of 7 MPa was uniformly applied from above the sheet surface of the disc-shaped sheet under an atmospheric pressure atmosphere using a heat press, and the treatment was performed at 100° C. for 10 minutes to obtain a compressed sheet. The product of the pressure (p) [MPa] and the time (t) [seconds] in this step is 4200.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 688 MPa, 42 MPa, and 240%. The results are shown in Table 1 below.

Further, in the same manner as in Example 1, a polishing pad was manufactured from the sheet having a thickness of 1.5 mm, and the wear rate was measured, and it was found to be 71 μm/hr. The results are shown in Table 1 below.

### Example 5

In the same manner as in Example 1, the thermoplastic polyurethane pellets obtained in Production Example 1 were supplied to a 3D printer to obtain a disc-shaped sheet having a thickness of 3 mm and a diameter of 40 cm.

Next, a spacer made of polytetrafluoroethylene with a thickness of 2.5 mm was placed as an outer frame of the disc-shaped sheet, and a pressure of 1 MPa was applied uniformly to the sheet surface of the disc-shaped sheet under a reduced pressure atmosphere with a degree of vacuum of 3 kPa using a vacuum heat press, and the treatment was performed at 180° for 15 seconds to obtain a compressed sheet. The product of the pressure (p) [MPa] and the time (t) [seconds] in this step is 15.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 725 MPa, 54 MPa, and 314%. The results are shown in Table 1 below.

Further, in the same manner as in Example 1, a polishing pad was manufactured from the sheet having a thickness of 1.5 mm, and the wear rate was measured, and it was found to be 57 μm/hr. The results are shown in Table 1 below.

### Example 6

In the same manner as in Example 1, the thermoplastic polyurethane pellets obtained in Production Example 1 were supplied to a 3D printer to obtain a disc-shaped sheet having a thickness of 3 mm and a diameter of 40 cm.

Next, a pressure of 3 MPa was uniformly applied from above the sheet surface of the disc-shaped sheet under a reduced pressure atmosphere of degree of vacuum of 3 kPa using a vacuum heat press, and the treatment was performed at 140° C. for 3 seconds to obtain a compressed sheet. The product of the pressure (p) [MPa] and the time (t) [seconds] in this step is 9.

Then, by grinding the surface of the obtained compressed sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 552 MPa, 33 MPa, and 169%. The results are shown in Table 1 below.

Further, in the same manner as in Example 1, a polishing pad was manufactured from the sheet having a thickness of 1.5 mm, and the wear rate was measured, and it was found to be 94 μm/hr. The results are shown in Table 1 below.

### Comparative Example 1

In the same manner as in Example 1, the pellets of thermoplastic polyurethane components obtained in Production Example 1 were supplied to a 3D printer to obtain a disc-shaped sheet having a thickness of 3 mm and a diameter of 40 cm.

Next, it was treated in a vacuum dryer at 120° C. for 1 hour under a reduced pressure atmosphere with a degree of vacuum of 3 kPa. No pressure was applied during this step.

Then, by grinding the surface of the sheet after the heat treatment, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 369 MPa, 26 MPa, and 140%. The results are shown in Table 1 below.

Further, in the same manner as in Example 1, a polishing pad was manufactured from the sheet having a thickness of 1.5 mm, and the wear rate was measured, and it was found to be 103 μm/hr. The results are shown in Table 1 below.

### Comparative Example 2

In the same manner as in Example 1, the pellets of thermoplastic polyurethane components obtained in Production Example 1 were supplied to a 3D printer to obtain a disc-shaped sheet having a thickness of 3 mm and a diameter of 40 cm.

Next, a pressure of 7 MPa was uniformly applied from above the sheet surface of the disc-shaped sheet under an atmospheric pressure atmosphere using a heat press, and the treatment was performed at room temperature (23° C.) for 1 hour. The product of the pressure (p) [MPa] and the time (t) [seconds] in this step is 25200. Note that no heat was applied in this step.

Then, by grinding the surface of the sheet after the pressure treatment, a disc-shaped sheet having a thickness of 1.5 mm and a disk-shaped sheet having a thickness of 500 μm were respectively obtained. The storage modulus, breaking stress, and elongation at break of the sheet with a thickness of 500 μm measured using the method described below were respectively 273 MPa, 12 MPa, and 9%. The results are shown in Table 1 below.

Further, in the same manner as in Example 1, a polishing pad was manufactured from the sheet having a thickness of 1.5 mm, and the wear rate was measured, and it was found to be 158 μm/hr. The results are shown in Table 1 below.

### Comparative Example 3

In the same manner as in Example 1, the pellets of thermoplastic polyurethane components obtained in Production Example 1 were supplied to a 3D printer to obtain a disc-shaped sheet having a thickness of 3 mm and a diameter of 40 cm.

Then, by grinding the surface of the disk-shaped sheet, a disc-shaped sheet having a thickness of 1.5 mm and a disc-shaped sheet having a thickness of 500 μm were respectively obtained. The storage modulus, breaking stress, and elongation at break of the sheet with a thickness of 500 μm measured using the method described below were respectively 242 MPa, 11 MPa, and 12%. The results are shown in Table 1 below.

Further, in the same manner as in Example 1, a polishing pad was manufactured from the sheet having a thickness of 1.5 mm, and the wear rate was measured, and it was found to be 166 μm/hr. The results are shown in Table 1 below.

### Comparative Example 4

In the same manner as in Example 1, the pellets of thermoplastic polyurethane components obtained in Production Example 1 were supplied to a 3D printer to obtain a disc-shaped sheet having a thickness of 3 mm and a diameter of 40 cm.

Next, a pressure of 3 MPa was uniformly applied from above the sheet surface of the disc-shaped sheet under a reduced pressure atmosphere of degree of vacuum of 3 kPa using a vacuum heat press, and the treatment was performed at room temperature (23° C.) for 2 minutes. The product of the pressure (p) [MPa] and the time (t) [seconds] in this step is 360. Note that no heat was applied in this step.

Then, by grinding the surface of the sheet after the pressure treatment, a disc-shaped sheet having a thickness of 1.5 mm and a disk-shaped sheet having a thickness of 500 μm were respectively obtained. The storage modulus, breaking stress, and elongation at break of the sheet with a thickness of 500 μm measured using the method described below were respectively 250 MPa, 12 MPa, and 11%. The results are shown in Table 1 below.

Further, in the same manner as in Example 1, a polishing pad was manufactured from the sheet having a thickness of 1.5 mm, and the wear rate was measured, and it was found to be 163 μm/hr. The results are shown in Table 1 below.

### <Storage Modulus of Resin Sheet>

A test piece having 5 mm wide and 30 mm length was cut out from the disc-shaped sheet with a thickness of 500 μm obtained in Examples and Comparative examples, so that the tensile direction was vertical to the formed pattern of the 3D printer as the radial direction of the disk. Then, the test piece was measured using a dynamic viscoelasticity measurement device (“DVE Rheo Spectral” manufactured by Rheology Co., Ltd.) at a temperature of 21° C., a frequency of 11 Hz, and a tensile condition to determine the storage modulus.

Note that as a reference, FIG. 4 represents a schematic plan view illustrating the outline of the disc-shaped sheet and the test pieces used in the measurement of storage modulus. Cutting out a test piece as the radial direction of the disk means as shown in FIG. 4, for a disc-shaped sheet 30, cutting out a test piece 32 in the radial direction of the disc-shaped sheet 30, so as to be vertical to a formed pattern 31 when forming a disc-shaped sheet by a 3D printer. FIG. 4 is a schematic plan view illustrating the meaning and outline of the radial direction of the disk according to cutting out of the test piece, and the distance from the center of the disk to the point where the test piece is cut out does not have to be as shown in FIG. 4.

### <Breaking Stress and Elongation at Break of Resin Sheet>

A dumbbell-shaped No. 3 test piece (40 mm between marked lines) was prepared by cutting out from the disc-shaped sheet with a thickness of 500 μm obtained in Examples and Comparative examples, so that the tensile direction was vertical to the formed pattern of the 3D printer as the radial direction of the disk. Then, using a tensile tester “3367” manufactured by Instron, a tensile test was conducted under a condition of a temperature of 23° C. and a tensile speed of 500 mm/min to determine the stress and elongation at break. Note that the average value of 5 points or more was used.

### <Abrasion Resistance (Wear Rate of Polishing Pad (Polishing Layer))>

The polishing pads obtained in Examples and Comparative Examples were attached to a polishing surface plate of a polishing device “BC-15” manufactured by MAT Inc. Then, under the conditions of dresser rotation speed 49 rpm, polishing pad rotation speed 50 rpm, and dresser load 25 N, the polishing pad surface (polished surface of the polishing layer) was under conditioning for 2 hours using a diamond dresser while flowing pure water at a rate of 150 mL/min. As the dresser, a dresser manufactured by Asahi Diamond Industrial Co., Ltd. (diamond count #100, diamond shape irregular type, base metal diameter 100 mm) was used. The depth of a groove before and after conditioning was measured at a point 100 mm from the center of the polishing pad in the radial direction of the disc, and the wear rate of the polishing layer of the polishing pad was measured.

TABLE 1

| | | Example 1 | Example 2 | Example 3 | Example 4 | Example 5 |
|---|---|---|---|---|---|---|
| Conditions | Atmosphere pressure | Reduced | Atmospheric | Reduced | Atmospheric | Reduced |
| of the step | | pressure | pressure | pressure | pressure | pressure |
| P | Spacer | absence | absence | presence | absence | presence |
| | Temperature [° C.] | 140 | 120 | 160 | 100 | 180 |
| | Pressure (p) [MPa] | 3 | 0.5 | 3 | 7 | 1 |
| | Time (t) [sec] | 120 | 3600 | 30 | 600 | 15 |
| | (p) × (t) | 360 | 1800 | 90 | 4200 | 15 |
| Evaluation | Storage modulus [MPa] | 713 | 691 | 729 | 688 | 725 |
| of Resin | Breaking stress [MPa] | 50 | 43 | 56 | 42 | 54 |
| sheet | Elongation at break [%] | 315 | 216 | 323 | 240 | 314 |
| | Wear rate [μm/hr] | 58 | 64 | 55 | 71 | 57 |

| | | Example | Comparative | Comparative | Comparative | Comparative |
|---|---|---|---|---|---|---|
| | | 6 | Example 1 | Example 2 | Example 3 | Example 4 |
| Conditions | Atmosphere pressure | Reduced | Reduced | Atmospheric | — | Reduced |
| of the step | | pressure | pressure | pressure | | pressure |
| P | Spacer | absence | absence | absence | — | absence |
| | Temperature [° C.] | 140 | 120 | 23 | — | 23 |
| | Pressure (p) [MPa] | 3 | 0 | 7 | — | 3 |
| | Time (t) [sec] | 3 | 3600 | 3600 | — | 120 |
| | (p) × (t) | 9 | 0 | 25200 | — | 360 |
| Evaluation | Storage modulus [MPa] | 552 | 369 | 273 | 242 | 250 |
| of Resin | Breaking stress [MPa] | 33 | 26 | 12 | 11 | 12 |
| sheet | Elongation at break [%] | 169 | 140 | 9 | 12 | 11 |
| | Wear rate [μm/hr] | 94 | 103 | 158 | 166 | 163 |

From Examples 1 to 6 and Comparative Examples 1 to 4, it was found that by applying pressure while heating after forming a sheet-shaped resin modeled article using a 3D printer, the storage modulus, breaking stress, and elongation at break of the resulting resin sheet were improved.

Furthermore, it was found that when the resin sheets obtained in Examples 1 to 6 were used as the polishing layer of the polishing pad, the abrasion resistance was significantly improved since the wear rate was lower than that of the resin sheets obtained in Comparative Examples 1 to 4. Therefore, it was found that the polishing pads having the resin sheets obtained in Examples 1 to 6 as the polishing layer have improved abrasion resistance of the polishing layer and have a longer usable life.

On the other hand, in Comparative Example 1 in which only heating was performed, and Comparative Examples 2 and 4 in which only pressure was applied, it was found that the physical properties of the resulting resin sheet were insufficiently improved or hardly improved.

This is presumed that when only heat treatment is performed on a resin sheet obtained by a 3D printer, for example by explaining using the schematic cross-sectional diagram shown in FIG. 2, by improving the mobility of polymer molecules, it is expected that the fusion will be improved due to the increase in the movement and entanglement of polymer molecules at the contact surface 11a between the resin blocks 11, however, the degree of improvement in the contact area is insufficient and the effect of improving the mechanical properties is limited.

Further, for example, it is presumed that when only pressure treatment is performed on a resin sheet obtained by a 3D printer, for example by explaining using the schematic cross-sectional diagram shown in FIG. 2, deformation of the resin block 11 is less likely to occur, and even if it occurs, the fusion of the resin blocks 11 on the contact surface 11a is insufficient, and there will little increase in the movement and entanglement of polymer molecules between the resin blocks, resulting that the effect of improving the mechanical properties was not obtained.

### INDUSTRIAL APPLICABILITY

By using the method for producing a resin sheet, the mechanical properties of a resin sheet obtained using a 3D printer can be significantly improved.

Therefore, when using a resin sheet obtained using a 3D printer, it is possible to use a resin sheet with further improved mechanical properties depending on the application. Furthermore, by using the method for producing a resin sheet described above, the mechanical properties of the resin sheet themselves are improved, therefore it also becomes possible to be used in applications which were previously not possible to use the resin sheet obtained by using a 3D printer, and which require higher modulus, strength, and elongation.

Furthermore, since the resin sheet obtained by using the above method for producing a resin sheet has a significantly improved abrasion resistance, for example, by using a polishing pad having a polishing layer obtained by using the method for producing a resin sheet described above, the abrasion resistance of the polishing layer can be improved, contributing to a longer life of the polishing pad.

### REFERENCE SIGNS LIST

1 Melt of Resin or Precursor of Resin
2 Nozzle of 3D printer
3 Modeling table
10 Sheet-shaped resin modeled article formed by 3D printer
11 Resin block
11a Contact surface of Resin blocks
12 Void
20 Compressed sheet obtained through Step P
A First layer formed by 3D printer
B Second layer formed by 3D printer
C Third layer formed by 3D printer
P Direction in which pressure was applied while heating in Step P
30 Disc-shaped sheet used in measurement of Storage modulus
31 Formed pattern when forming disc-shaped sheet by 3D printer
32 Test piece cut out for storage modulus test

1: A method for producing a resin sheet, the method comprising:
Step P: applying pressure (p) to a sheet-shaped resin modeled article formed by a 3D printer while heating at a heat temperature, and deforming the sheet-shaped resin modeled article to obtain a compressed sheet.

2: The method according to claim 1,
wherein the heat temperature is 80° C. or higher.

3: The method according to claim 1,
wherein the pressure (p) is 0.1 MPa or more.

4: The method according to claim 1,
wherein a spacer is used in the step P.

5: The method according to claim 1,
wherein a product of the pressure (p) measured in MPa and time (t) measured in seconds for applying the pressure (p) satisfies the following formula (i):
5≤p×t≤5000 Formula (i):

6: The method according to claim 1,
wherein the step P is performed under a reduced pressure atmosphere.

7: The method according to claim 1,
wherein the sheet-shaped resin modeled article is a modeled article of polyurethane.

8: The method according to claim 1, further comprising the following step M before the step P,
Step M: discharging a melt or a precursor of a resin from a nozzle and solidifying the resin to form the sheet-shaped resin modeled article using the 3D printer.

9: The method according to claim 8,
wherein the melt or the precursor of the resin passes through a filter before discharged from the nozzle of the 3D printer in the step M.

10: The method according to claim 8,
wherein the resin is a thermoplastic resin and the solidifying of the thermoplastic resin is performed by cooling.

11: The method according to claim 10,
wherein the thermoplastic resin is a thermoplastic polyurethane.

12: The method according to claim 1, further comprising the following step T after the step P,
Step T: making a thickness of the compressed sheet obtained in the step P thin using one or more methods selected from the group consisting of cutting, machining, and grinding.

13: The method according to claim 1,
wherein the resin sheet is a polishing layer for a polishing pad.

14: A polishing pad, comprising:
a polishing layer obtained by using the method according to claim 13.
